(19) United States
(12) Patent Application Publication
(10) Pub. No.: US 2013/0087921 A1
(43) Pub. Date: Apr. 11, 2013

(54) Semiconductor Arrangement for Galvanically Isolated Signal Transmission and Method for Producing Such an Arrangement

(71) Applicant: INFINEON TECHNOLOGIES AG, Neubiberg (DE)

(72) Inventor: Uwe Wahl, Muenchen (DE)

(73) Assignee: INFINEON TECHNOLOGIES AG, Neubiberg (DE)

(21) Appl. No.: 13/621,965

(22) Filed: Sep. 18, 2012

(30) Foreign Application Priority Data
Sep. 19, 2011 (DE) 102011082955.5

(51) Int. Cl. H01L 23/498; H01L 21/50

(52) U.S. Cl. CPC H01L 23/498; H01L 21/50
USPC 257/773; 438/106

(57) ABSTRACT

A semiconductor arrangement includes an artificial chip having a semiconductor chip and an electrically insulating molding compound. The semiconductor chip has circuit structures and is embedded into the molding compound at all sides other than at a base area of the semiconductor chip in such a way that a base area of the artificial chip is enlarged by the molding compound relative to the base area of the semiconductor chip. A thin-film substrate is applied to the enlarged base area and extends beyond the base area of the semiconductor chip into the enlarged base area. The substrate has at least two layers composed of nonconductive material between which a structured metallization is disposed. A first coil is formed by one or a plurality of structured metallization layers in the substrate. A second coil is magnetically and/or capacitively coupled to the first coil and galvanically isolated from the first coil.

### PRIORITY CLAIM

This application claims priority to German Patent Application No. 10 2011 082 955.5, filed on 19 Sep. 2011, the content of said German application incorporated herein by reference in its entirety.

### TECHNICAL FIELD

The invention relates to a semiconductor arrangement for galvanically isolated signal transmission, and to a method for producing such a semiconductor arrangement.

### BACKGROUND

Signal transmission in the case of potential differences between transmitting and receiving ends usually requires the use of level shifters, optocouplers or magnetic/capacitive couplers. Level shifters and magnetic couplers can be concomitantly monolithically integrated into the integrated circuit, while optocouplers have to be concomitantly installed on a printed circuit board, for example, outside the integrated circuit. Besides this additional space requirement, optocouplers have a limited lifetime, a lower operating frequency and a high power loss. Level shifters conceptually do not allow galvanic isolation and, on account of switching losses, have a maximum operating frequency of less than 300 kHz, which is often too low for fast signal transmission. Concomitantly integrating magnetic/capacitive couplers into an integrated circuit typically require specific production engineering adaptations of the basic circuit technology. In the case of magnetic couplers, for example, for a good magnetic coupling it is necessary to satisfy the stipulation of a small distance between the coils, as a result of which, however, the isolation between the coils and thus overall the dielectric strength of the coupler are reduced. Another prerequisite for a good magnetic coupling is a large coil area, but that requires a circuit having a large area which in turn entails high costs. Finally, magnetic couplers require a low resistance of the coupling loops and thus a thick metallization in the circuit in order to allow high current densities in the coils, but this requires complex and thus expensive production processes.

### SUMMARY

According to an embodiment of a semiconductor arrangement for galvanically isolated signal transmission, the semiconductor arrangement comprises an artificial chip. The artificial chip includes a semiconductor chip with circuit structures embedded into an electrically insulating molding compound at all sides other than at a base area of the semiconductor chip in such a way that a base area of the artificial chip is enlarged by the molding compound relative to the base area of the semiconductor chip. The semiconductor arrangement further comprises a thin-film substrate applied to the enlarged base area and which extends beyond the base area of the semiconductor chip into the enlarged base area. The substrate has at least two layers composed of nonconductive material, between which a structured metallization is introduced. The semiconductor arrangement also comprises first and second coils. The first coil is formed by one or a plurality of structured metallization layers in the substrate. The second coil is magnetically and/or capacitively coupled to the first coil and galvanically isolated from the first coil.

A method for producing such a semiconductor arrangement comprises: embedding a semiconductor chip with circuit structures into an electrically insulating molding compound to form an artificial chip in such a way that the semiconductor chip is embedded into the molding compound at all sides other than at a base area of the semiconductor chip and a base area of the artificial chip is enlarged relative to the base area of the semiconductor chip; applying a first dielectric layer to the artificial chip; applying a seed layer to the first dielectric layer; applying a metallization to the seed layer; etching at least one coil-shaped structure in the metallization; and applying a second dielectric layer to the metallization with the at least one coil-shaped structure.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 shows in cross section a semiconductor arrangement produced using wafer level ball grid array technology;

FIG. 2 shows in plan view the underside of the semiconductor arrangement according to FIG. 1;

FIG. 3 shows the cross section a part of the arrangement according to FIG. 1;

FIG. 4 shows in plan view the partial arrangement according to FIG. 3;

FIG. 5 shows in cross section a development of the partial arrangement according to FIG. 3;

FIG. 6 shows in plan view the top side of the partial arrangement according to FIG. 5;

FIG. 7 shows in cross section a semiconductor arrangement produced using embedded wafer level ball grid array technology;

FIG. 8 shows in plan view the underside of the semiconductor arrangement according to FIG. 7;

FIG. 9, which includes FIGS. 9a through 9f, shows schematically selected intermediate products during the production of a semiconductor arrangement according to FIG. 7;

FIG. 10 shows the semiconductor arrangement according to FIG. 1 with coils introduced into the redistribution planes;

FIG. 11 schematically shows a configuration of a coil arranged in a redistribution plane with one turn;

FIG. 12 schematically shows a configuration of a coil arranged in a redistribution plane with two turns and one redistribution contact-connection;

FIG. 13 schematically shows a further configuration of a coil arranged in a redistribution plane with two turns and one redistribution contact-connection;

FIG. 14 schematically shows a configuration of a coil arranged in a redistribution plane with three turns, two redistribution contact-connections and one tap;

FIG. 15 schematically shows a configuration of two coils arranged in two redistribution planes with in each case two turns;

FIG. 16 schematically shows a configuration of two coils arranged in two redistribution planes with in each case one turn;

FIG. 17 shows in cross section a semiconductor arrangement with two chips and two coils;

FIG. 18 shows the circuit diagram of the semiconductor arrangement according to FIG. 17;

FIG. 19 shows in cross section a semiconductor arrangement with one chip and three planar individual coils stacked one above another; and

FIG. 20 shows in plan view planar individual coils such as are used in the arrangement according to FIG. 19.

### DETAILED DESCRIPTION

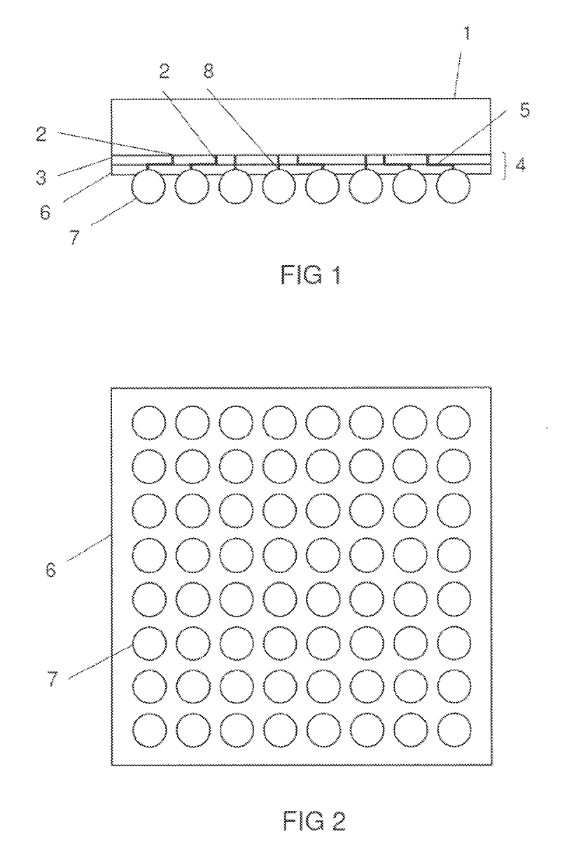

FIGS. 1 and 2 show by way of example a semiconductor arrangement using wafer level ball grid array technology (encapsulation at the wafer level), also referred to herein as WLB for short. In this case, a semiconductor chip 1 has a number of (vertical) contact elements 2 which are fitted to the underside relative to the view in accordance with FIG. 1. For this purpose, a (horizontal) dielectric layer 3 containing for example silicon, such as silicon oxide, for example, is applied on the underside of the semiconductor chip 1. A metallization layer is in turn provided on the dielectric layer 3, which metallization layer can contain copper or aluminum and is structured by etching during the production process in order to produce conductor tracks 5. The metal layer can, for example, be sputtered onto the dielectric layer 3, coated with a photosensitive resist layer (photo resist) and exposed using an exposure mask that images the desired structure. After a development process, the structure thus produced is etched and, if appropriate, subsequently plated. The typical thickness of the conductor tracks 5 produced in this way is in the range of 3 to 20 μm and the average width of the resulting lines is 20 μm. The contact elements 2 are situated in contact holes of the dielectric layer 3 and produce an electrical contact between the conductor tracks 5 and the circuit structures on the chip 1, which can comprise for example, connection pads specifically provided for contact-connection. A further dielectric layer 6 applied on the metallization layer can contain polyamide, for example, and have holes for further contact elements 8, through which the conductor tracks 5 are brought into electrical contact with solder balls 7. In this case, the solder balls 7 can be arranged in recesses provided in the dielectric layer 6. In this case, the two dielectric layers 3 and 6 applied to the chip 1 form a redistribution thin-film substrate 4 pervaded by conductor tracks 5 and contact elements 2, 8.

The solder balls 7 are arranged in a specific pattern, which typically has the form of a matrix as illustrated in FIG. 2. Furthermore, at various nodes of the matrix it is possible for no solder balls to be provided or it is possible to use patterns deviating completely from a matrix in the arrangement of the solder balls.

FIG. 3 shows in detail how the solder ball 7 is positioned in a recess in the dielectric layer 6, and how the solder ball 7 is in contact with the conductor track 5 in the recess. In this case—as already explained—the conductor track 5 is embedded between the two electrically insulating dielectric layers 3 and 6 and reaches the chip 1, to make contact with the chip 1 only at the level of the downwardly extending contact element 2. At the other end of the conductor track 5, the solder ball 7 bears on the conductor track 5 through the recess in the dielectric layer 6 and makes contact with the conductor track 5 i.e. in the case shown simultaneously also forms the contact element 8 from FIG. 1. The arrangement shown in FIG. 3 is rotated upward by 180° relative to the arrangement shown in FIG. 1.

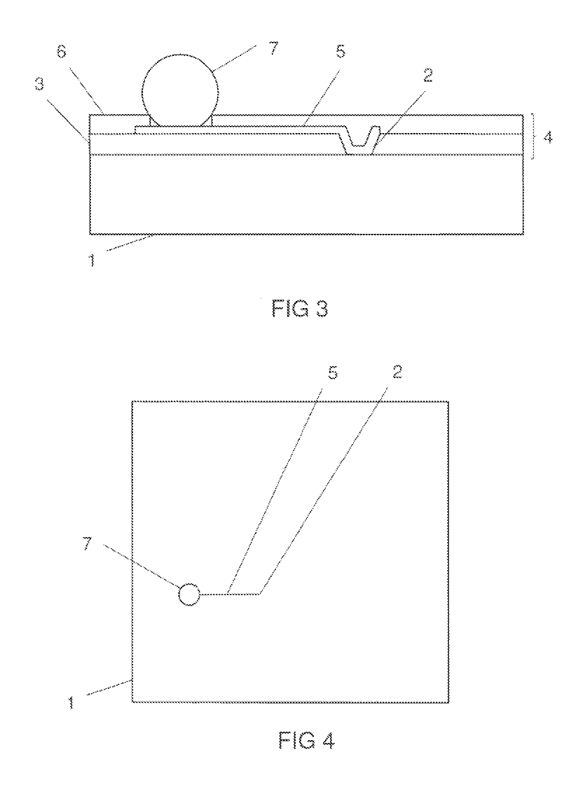

FIG. 4 illustrates the position of the solder ball 7 shown in FIG. 3 and of the conductor track 5 together with contact element 2 from the surface of the chip 1, that is to say referring to FIG. 3 from the top side thereof.

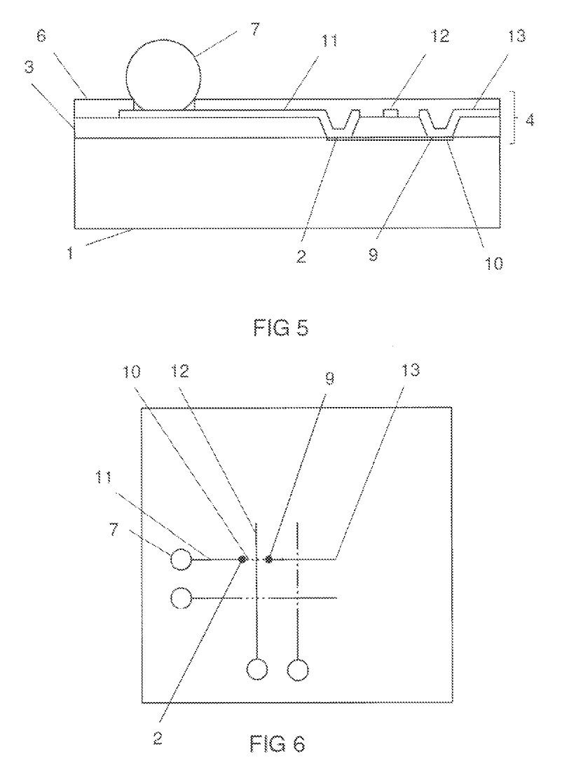

While the conductor track 5 is oriented only in one direction in the case of the embodiment according to FIG. 3, conductor tracks 11, 13 can also run at right angles with respect to a conductor track 12 in the case of the arrangement shown in FIGS. 5 and 6. In this case, referring to FIG. 6 the conductor tracks 11 and 13 run from left to right and are in this case interrupted by the conductor track 12 running perpendicular to the plane of the drawing. In order nevertheless to bring about a conductive intersection, contact elements 2 and 9 are provided at those ends of the conductor tracks 11 and 13 which face the conductor track 12, the contact elements 2 and 9 in turn reaching as far as the chip 1, at the surface of which between the contact elements 2 and 9 a conductive layer 10 in contact with the contact elements 2 and 9 electrically connects the contact elements 2 and 9 to one another. The conductor track 12 runs across the conductive layer 10 and substantially perpendicular to the conductive layer 10 in a manner electrically insulated from the conductive layer 10. In this case, the conductor tracks 11, 12, 13 can be parts of one or a plurality of coils.

It can be seen from the illustration in FIG. 6 that it is also possible to choose patterns which can have fewer matrix points and thus fewer solder balls by comparison with the arrangement shown in FIG. 2, in which case the area thus liberated can then be used—as will be shown comprehensively below—for the formation of at least one planar coil. A further development of the wafer level ball grid array technology (WLB) shown in FIGS. 1 to 6 is so-called inverted wafer level ball grid array technology (eWLB), where all required processing steps are carried out on the semiconductor wafer, for example silicon wafer. Compared with traditional package technologies such as, for example, ball grid array technology, this allows the production of extremely small and flat packages having excellent electrical and thermal properties in conjunction with low production costs. In the case of WLB technology, all solder contacts have to fit the base area of the chip. Therefore, only components with a limited number of contacts can be packaged in this way. However, even if the number of contacts is small, but at least one coil is intended to be accommodated in the carrier as in the case of the present invention the limits of this technology are apparent.

By contrast, so-called embedded wafer level ball grid array technology (eWLB) makes it possible to produce components with many contacts. In this case, unlike in the case of traditional WLB technology, the package is not produced on the semiconductor wafer, but rather on an artificial wafer. For this purpose, a finished processed wafer is sawn into individual chips and the singulated chips are transferred to a carrier plate. In this case, the chips are placed at a greater distance from one another than was the case on the silicon wafer. The interspaces and the edge region are filled by a molding compound. After the curing thereof, an artificial wafer results that forms a mold frame around the chips, on which additional solder contacts can be accommodated. After the production of the artificial wafer, so-called reconstitution, the electrical connections to the soldering connections are then produced using thin-film technology, as in the case of traditional WLB technology. With this technology it is possible to produce as many additional solder contacts as desired or space for the arrangement of other arbitrary metallization structures. The further processing of the artificial, enlarged wafer then corresponds, in principle, to that of the customary wafer. As a result, eWLB technology can also be used for space-intensive applications, without having to take up more pure chip area for such accommodations.

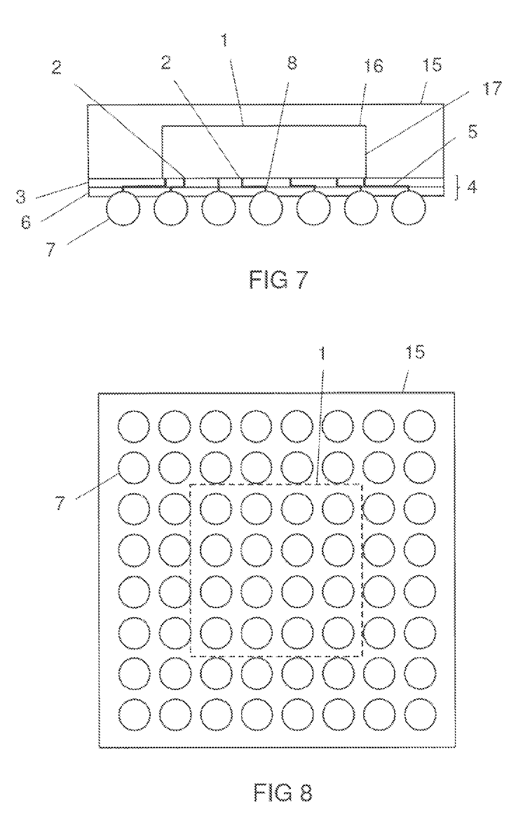

A semiconductor arrangement produced with eWLB technology is illustrated in FIG. 7. By comparison with the arrangement shown in FIG. 1, the chip 1 is smaller than the thin-film substrate 4 comprising the two dielectric layers 3 and 6 and the conductor tracks 5 and contact elements 2 and 8 enclosed therein. An encapsulation 15 composed of molding compound is additionally provided, such that the encapsulation 15 and the chip 1 produce an artificial, enlarged “chip” after the sawing of the artificial wafer. The molding compound is, for example, a polymer such as, for instance, a polymide or an epoxy resin comprising a high quantity of silicon dioxide (for example more than 90% by weight). The encapsulation 15 covers the chip 1 at its top side 16 and side areas 17 in an insulating manner toward the outside, the encapsulation 15 extending over the entire area of the thin-film substrate 4 in a horizontal plane. As can be seen in FIG. 7 and in particular from FIG. 8, the area occupied by the chip 1 is therefore smaller than the base area of the encapsulation 15 and the thin-film substrate 4. Therefore, more area for making contact by means of the solder balls 7 or else, with a smaller number of contacts, more area for one or a plurality of coils is available.

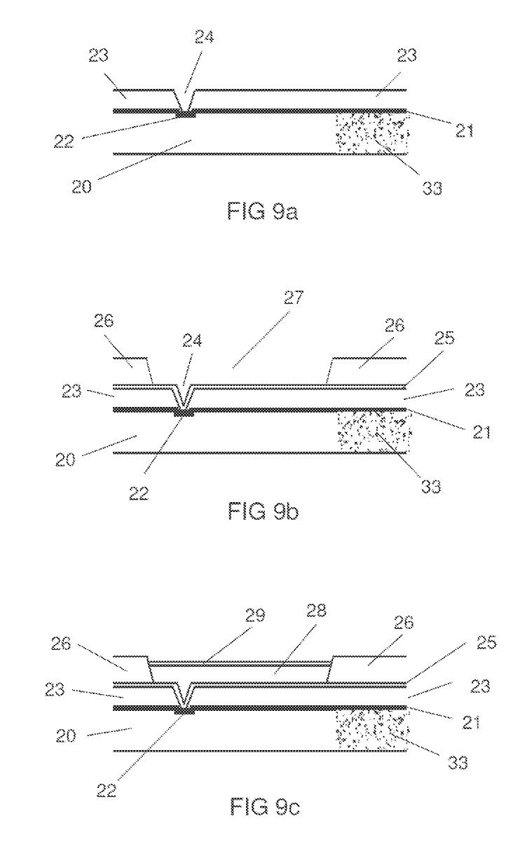

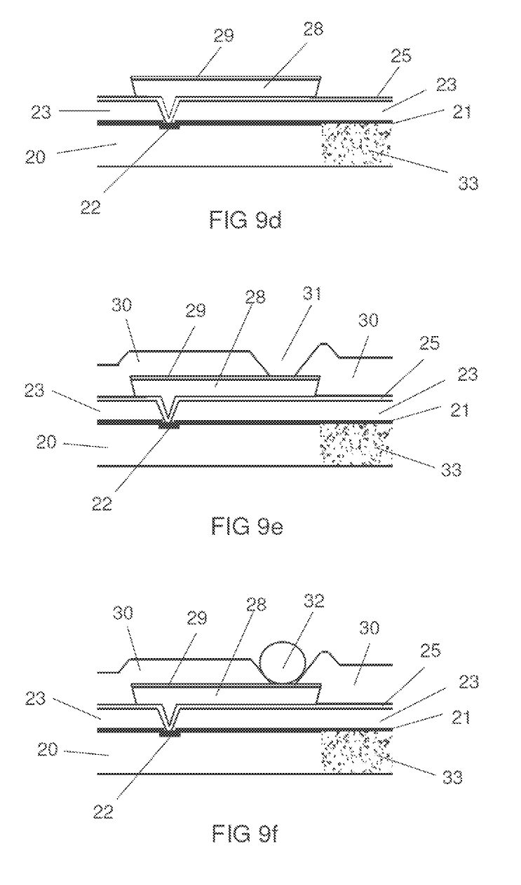

FIG. 9 illustrates, on the basis of intermediate views 9a through 9f, an exemplary embodiment of a method for producing a semiconductor arrangement according to the invention. In this case, the method shown is not only suitable for WLB technology but can also be used with eWLB technology or comparable technologies.

The method involves firstly applying to the top side of a silicon wafer 20, which has a passivation layer 21 and a cutout situated therein, an electrically conductive connection pad 22 composed of aluminum, for example, in the cutout. An electrically insulating dielectric layer 23 composed of silicon oxide, for example, having a thickness of 6 μm, for example, is then applied above the passivation layer 21, the dielectric layer 23 having a cutout, called contact hole 24 hereinafter, at the location of the connection pad 22. The resulting intermediate structure is illustrated in FIG. 9a.

A metallization seed layer 25 composed of, for example, firstly titanium-tungsten (thickness of approximately 50 nm) and then copper (thickness of approximately 150 nm) is deposited onto the dielectric layer 23 by means of sputtering, for example. Afterward, a photosensitive resist 26 (photoresist) is applied to the metallization seed layer 25, wherein a relatively large-area window 27 is cut out in the region of the contact hole 24. The seed layer 25 can be deposited, for example, by means of sputtering in an O₂/He plasma atmosphere. The window 27 can be produced by exposure, development and etching. The resulting intermediate structure is illustrated in FIG. 9b.

Afterward, in the window 27, a redistribution metallization layer 28, referred to herein as RDL (RDL=redistribution layer) for short, is produced, which is covered by the metallization seed layer 25 on its underside and by a further metallization seed layer 29 at its top side. The RDL metallization layer 28 consisting of copper for example, can be produced, for example, by means of copper activation (Cu activation) or copper plating (Cu plating). The resulting intermediate structure is illustrated in FIG. 9c.

Afterward, the resist 26 is completely removed and, if appropriate, the titanium-tungsten layer and parts of the copper layer of the upper metallization seed layer 29 are removed by etching. The resulting intermediate structure is illustrated in FIG. 9d.

This is then followed by the application of a soldering resist coating 30, which is formed by a further dielectric layer composed of silicon oxide, for example. The soldering resist coating 30 has a window 31, which uncovers the RDL metallization layer 28, but at a horizontal position that differs from that of the contact hole 24. The window 31 can in turn be produced by exposure, development and etching. The resulting intermediate structure is illustrated in FIG. 9e.

Afterward, with flux being applied beforehand, a solder ball 32 is introduced into the window 31 by a reflow method. The solder (for example SnAgCu) then produces a conductive connection to the RDL metallization layer 28. The resulting intermediate structure is illustrated in FIG. 9f.

As already mentioned above, the method shown is suitable for both WLB and eWLB technology, such that in the latter case (as indicated as an option in FIG. 9) a portion of the conductor tracks and of the substrate can extend across an encapsulation 33 instead of exclusively the silicon wafer 20.

The RDL metallization layer 28 can be structured in almost any arbitrary manner, such that instead of connections between the solder ball 32 and the contact in contact hole 24 it is also possible to realize coils in a similarly simple manner, which can then be electrically connected to a circuit formed in the chip 1 via the contact in the contact hole 24. This is explained in greater detail in the following examples.

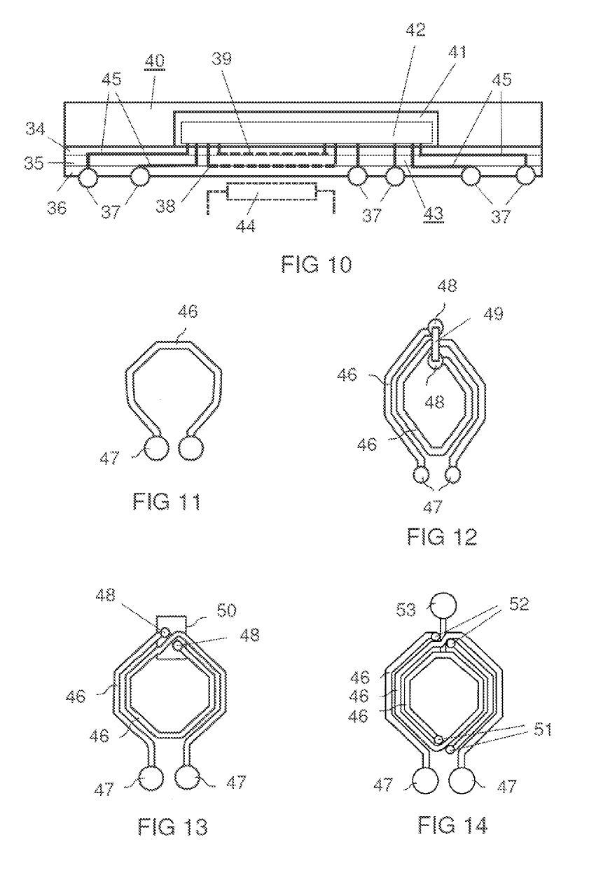

In the case of an embodiment of the invention as shown in FIG. 10, a chip 41 having an integrated circuit structure 42 is embedded into a cured molding compound 40, the underside of the chip 41 being disposed level with the molding compound 40. On the underside of the chip 1 and molding compound 40 there is situated a thin-film substrate 43 applied thereto and comprising three dielectric layers 34, 35, 36. Between the dielectric layers 34 and 35, and 35 and 36, metallization layers that are structured in two planes are provided, which are structured firstly as conductor tracks 45 for the purpose of redistributing wiring and secondly also as (two stacked, that is to say arranged one above the other in two planes) coils 38 and 39. Finally, solder balls 37 serve as a connecting element between the semiconductor arrangement and a printed circuit board (not shown), wherein it is appropriate, for example, for the semiconductor arrangement to be mounted on the printed circuit board by means of flip-chip technology. The horizontally applied conductor tracks 45 therefore have the structure of a connecting line or coil, while the vertically applied contact-connections principally serve only as connecting lines in particular for externally making contact with the chip 41.

The coils 38 and 39 can be interconnected with the chip 41 by means of the circuit structures 42 either to form a transformer having two galvanically isolated coils, or else a single coil having two winding planes. In the latter case, a further coil 44 can be provided in or on the external printed circuit board, for example, the further coil 44 being driven externally.

In this case, the coils 38 and 39 can be configured, for example, as illustrated in FIGS. 11 to 16. The coil shown in FIG. 11 has only a single turn, at the two ends of which are situated in direct proximity to one another, i.e. without conductive areas in between, two contact-making pads 47 for making contact with vertical contact elements. Coils having two turns in one plane are shown in FIGS. 12 and 13, wherein here as well the contact-making pads 47 are directly adjacent to one another. In order to achieve this in the case of more than one turn, a respective redistribution contact-connection is necessary, which, in the exemplary embodiment according to FIG. 12, is achieved by means of further contact pads 48 and an interposed electrically conductive bridge 49, which guides one turn across the other turn. In the exemplary embodiment according to FIG. 13, the redistribution contact-connection is achieved by one turn being led through under the other turn by means of a deeper metallization 50. Proceeding from the exemplary embodiment according to FIG. 13, the exemplary embodiment according to FIG. 14 is extended by one turn and comprises a redistribution contact-connection by means of a deeper metallization 51 and a redistribution contact-connection by means of a deeper metallization 52, wherein a coil tap 53, which leads to a further contact-making pad 47, is also provided in the place of the metallization 52 in a further metallization plane situated in between.

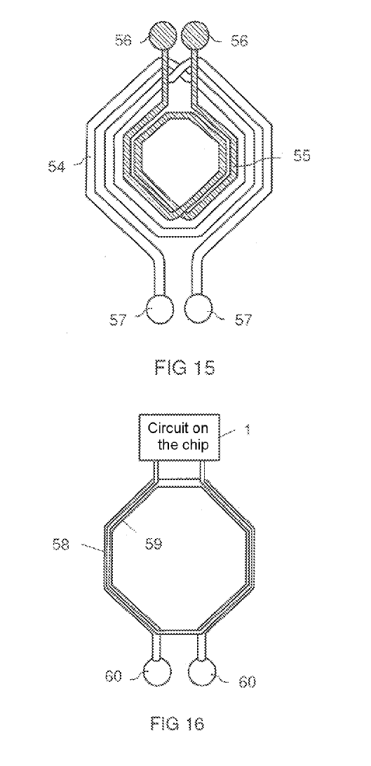

FIG. 15 shows an exemplary embodiment of a coreless transformer comprising two coils 54 and 55, each of which has more than one turn and in which the respective contact-making pads 56 and 57 are in each case adjacent to one another. The two coils 54 and 55 can lie on different metallization planes as shown in this case or else on the same metallization plane in the case of the configuration shown, since the coil 55 is arranged within the cross-sectional opening of the coil 54. In the latter case, however, corresponding line crossovers or redistribution contact-connections would then have to be provided.

FIG. 16 shows an embodiment of two coils 58, 59, which are embodied in a manner lying directly one above the other in different metallization planes, but with a cross-sectional opening of identical size. In this case, one of the coils, 59, is electrically connected to a driving and/or evaluation circuit on the chip 1, while the other coil can be externally contact-connected via contact-making pads 60.

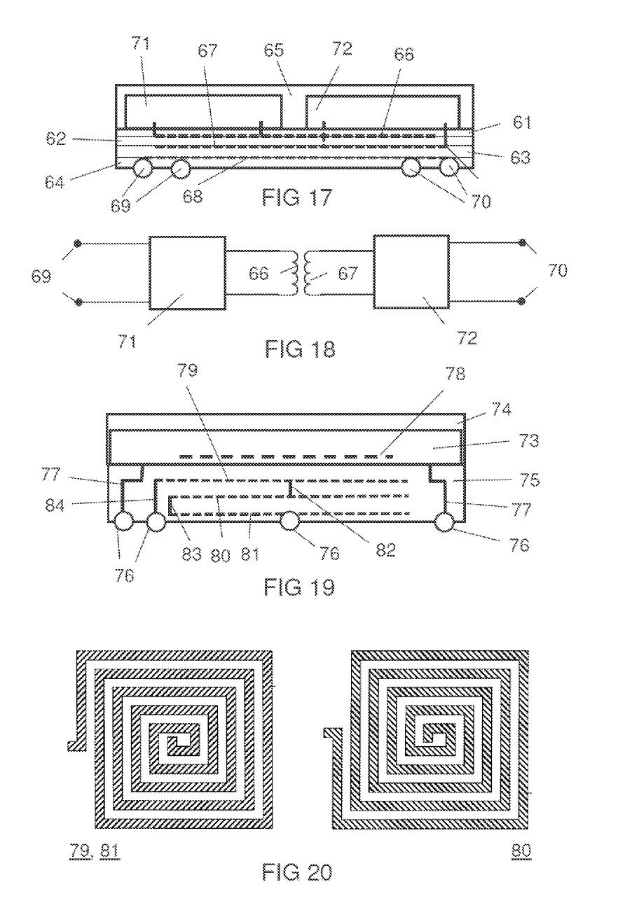

FIG. 17 shows a semiconductor arrangement according to the invention comprising two chips 71 and 72 produced by means of molding compound 65 using eWLB technology. In this configuration of the invention, the artificial wafer was sawn in such a way that a semiconductor arrangement always comprises two chips 71 and 72. The two chips 71 and 72 can be contact-connected externally via solder balls 69 and 70, respectively, and coupled via a coreless transformer with coils 66 and 67, wherein the coils 66 and 67 are embedded in different metallization planes in a substrate 68. In this case, the chips 71 and 72 are enclosed by the molding compound 65 apart from the solder balls 69 and 70, respectively, wherein the molding compound 65 and substrate 68 have mutually corresponding, i.e. approximately equal or identical extents.

The electrical interconnection in the case of the arrangement shown in FIG. 17 is illustrated in FIG. 18. The two coils 66 and 67 are in this case each in electrical contact with circuits in the chips 71 and 72, which in turn serve with the solder balls 69 and 70 for the external circuitry connection thereof. The circuits in the chips 71 and 72 can comprise transmitting and/or receiving circuits (transceivers), for example, which transmit signals at different transmission frequencies in respectively one of the two transmission directions, such that a bidirectional signal transmission between the chips 71 and 72 is allowed. The two circuits are galvanically isolated from one another, that is to say no current flows from one circuit into the other circuit. For transmission between the two coils 66 and 67 it is possible to use high-frequency signals modulated in any desired manner, for example.

FIG. 19 shows an exemplary embodiment of a semiconductor arrangement comprising a chip 73, which is embedded into a molding compound 74 and in the periphery of the base area of the chip 73 has a substrate 75 comprising at least three metallization planes. The chip 73 is connected to at least two solder balls 76 for external contact-connection via vertical conductor tracks 77 and intermittent horizontal conductor tracks in one of the metallization planes. The chip 73 has, inter alia, internal circuit structures for conditioning, evaluation and transmission of signals via a coreless coil 78 electrically connected thereto. In the at least three metallization planes, from three of which in each case a coil 79, 80, 81 are arranged one above or below the other and connected to one another in a vertical direction via vertical connecting lines 82, 83. The coils 79, 80, 81 are embodied as shown in FIG. 20 as planar, spiral coils, wherein the coils 79 and 81 have the same winding sense and the coil 80 has an opposite winding sense by comparison therewith. A signal current is therefore fed in for example at the outer connection for coil 79, in this case flows as far as the inner connection, where it is led via the vertical conductor track structure 82 to the central contact of the coil 80, flows there to the outer contact, where it is conducted via the vertical conductor track structure 83 to the outer connection of the coil 81, where it in turn flows to the inner contact and from there is finally conducted toward the outside. In this way, from three planar windings a three-dimensional coil is produced in which the individual planar coils are arranged in a stacked manner. However, a stacked arrangement is also possible in the same way with different numbers and also with a plurality of coils operated in a manner electrically isolated from one another.

The present invention utilizes the magnetic/capacitive coupling of adjacent coils that are spaced apart. The coils are, however, not (exclusively) realized in the integrated circuit itself, but rather at least partly in the package. In order to ensure a good coupling in this case, a production method is used which enables conductor tracks to be introduced into the package with very precise tolerances. The method according to the invention for producing such semiconductor arrangements is a development of wafer level ball grid array package technology or of embedded wafer level ball grid array package technology, which were developed in order to distribute the many closely adjacent connection pads of modern integrated circuits such that the circuits can be soldered by the so-called reflow method. The method affords an alignment accuracy of a few μm and minimal fluctuations in the region of 10 μm. These properties are now advantageously used according to the invention for the production of coils for magnetic/capacitive couplers. The method according to the invention makes it possible to produce one or a plurality of wiring planes (structured metallization planes), such that the coils provided for coupling either can both be positioned outside the integrated circuit (for example in a dielectric layer) or one coil can be positioned on the chip of the integrated circuit and the other outside the chip.

Accordingly, the customary processes for producing the integrated circuit, in particular the chip, can be largely maintained. Furthermore, no additional chip area is required for the coils, thus resulting in lower total cost. Since the coil area in the case of WLB/eWLB technology is limited only to the base area of the package (rather than of the small chip) and, unlike in the case of coils integrated into the chip, the coil area does not influence the chip cost, the coupling factor between the coils can be significantly improved. Simplified driving with a lower limiting frequency is possible by means of larger coils. A further advantage is that WLB/eWLB technology makes possible very low coil resistances by virtue of the relatively thick metallization of more than 6 μm or even 10 μm. This additionally improves the coupling properties.

The possibilities afforded by such improved coupling properties can be utilized to increase the distance between coupling coils, with the result that it is possible to achieve very high isolation classes between the coupling coils. In contrast thereto, monolithic solutions necessitate complex individual process optimizations for the deposition of thick isolation layers, which moreover again interact with the package used, as a result of which product-specific problems can occur.

With the coupling coils being at least partly shifted out of the chip into the package while making use of the possibilities afforded by WLB and eWLB technologies, it is now possible to provide couplers for a wide variety of isolation classes more cost-effectively and independently of the underlying circuit technology. Furthermore, the requirements made of the driving electronics for the coupling coils are reduced on account of improved coupling properties.

In particular, provision is made for the redistribution layer (redistribution metallization layer) of a WLB/eWLB package to be used for realizing the coupling coils. This can be affected, for example, as follows. A one-ply redistribution layer can be used, wherein the last metallization plane of the integrated circuit with a coil in the redistribution layer forms the coupler. In the case of a two-ply redistribution layer, both coils are realized in the metallization of the redistribution layer. In the case of a redistribution layer having three or more plies, it is possible to use stacked coils on different layers for forward and return channels. The dielectric between chip and metallization or between the redistribution metallizations can be substantially freely adapted to the reverse voltage requirements in terms of thickness.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A semiconductor arrangement for galvanically isolated signal transmission, comprising:
an artificial chip including a semiconductor chip and an electrically insulating molding compound, the semiconductor chip having circuit structures and being embedded into the molding compound at all sides other than at a base area of the semiconductor chip in such a way that a base area of the artificial chip is enlarged by the molding compound relative to the base area of the semiconductor chip;
a thin-film substrate applied to the enlarged base area of the artificial chip and extending beyond the base area of the semiconductor chip into the enlarged base area, the substrate having at least two layers composed of nonconductive material between which a structured metallization is disposed;
a first coil formed by one or a plurality of structured metallization layers in the substrate; and
a second coil magnetically and/or capacitively coupled to the first coil and galvanically isolated from the first coil.

2. The semiconductor arrangement as claimed in claim 1, wherein the second coil is formed by one or a plurality of structured metallizations in the substrate.

3. The semiconductor arrangement as claimed in claim 1, wherein the second coil is formed by a shaped circuit structure in the semiconductor chip.

4. The semiconductor arrangement as claimed in claim 1, wherein the second coil is disposed external to the artificial chip.

5. The semiconductor arrangement as claimed in claim 1, wherein the first coil is formed in a metallization layer disposed closest to the semiconductor chip and the second coil is formed in a circuit structure of the semiconductor chip.

6. The semiconductor arrangement as claimed in claim 1, wherein the substrate has at least two metallization layers and the first and second coils are each formed in a different one of the metallization layers.

7. The semiconductor arrangement as claimed in claim 6, wherein the coils formed in the metallization layers of the substrate are stacked one above another perpendicularly to the metallization layer planes.

8. The semiconductor arrangement as claimed in claim 6, wherein each metallization layer has a thickness of at least 6 micrometers.

9. The semiconductor arrangement as claimed in claim 8, wherein each metallization layer has a thickness of at least 10 micrometers.

10. The semiconductor arrangement as claimed in claim 6, wherein at least one of the coils realized in the metallization layers of the substrate is electrically connected to the semiconductor chip.

11. The semiconductor arrangement as claimed in claim 1, wherein the substrate has at least three metallization layers and the first coil, the second coil and at least one third coil are each formed in a different one of the metallization layers.

12. The semiconductor arrangement as claimed in claim 11, wherein the coils formed in the metallization layers of the substrate are stacked one above another perpendicularly to the metallization layer planes.

13. The semiconductor arrangement as claimed in claim 11, wherein each metallization layer has a thickness of at least 6 micrometers.

14. The semiconductor arrangement as claimed in claim 13, wherein each metallization layer has a thickness of at least 10 micrometers.

15. The semiconductor arrangement as claimed in claim 11, wherein at least one of the coils realized in the metallization layers of the substrate is electrically connected to the semiconductor chip.

16. The semiconductor arrangement as claimed in claim 1, wherein the at least two layers composed of nonconductive material are dielectric layers containing silicon.

17. The semiconductor arrangement as claimed in claim 1, wherein the first coil has a larger cross-sectional area than the semiconductor chip.

18. A method for producing a semiconductor arrangement, the method comprising:
embedding a semiconductor chip with circuit structures into an electrically insulating molding compound to form an artificial chip in such a way that the semiconductor chip is embedded into the molding compound at all sides other than at a base area of the semiconductor chip and a base area of the artificial chip is enlarged relative to the base area of the semiconductor chip;
applying a first dielectric layer to the artificial chip;
applying a seed layer to the first dielectric layer;
applying a metallization to the seed layer;
etching at least one coil-shaped structure in the metallization; and
applying a second dielectric layer to the metallization with the at least one coil-shaped structure.

19. The method as claimed in claim 18, further comprising:
forming cutouts in the first dielectric layer; and
electrically connecting the metallization to the semiconductor chip at the cutouts.

20. The method as claimed in claim 18, further comprising:
forming cutouts in the second dielectric layer; and
electrically connecting the metallization to external contact elements at the cutouts.
